(19) United States
(12) Patent Application Publication
(10) Pub. No.: US 2025/0253225 A1
(43) Pub. Date: Aug. 7, 2025

(54) REDISTRIBUTION LAYER HAVING GUARD MEMBERS AND METHOD OF MANUFACTURING THE SAME

(71) Applicant: TAIWAN SEMICONDUCTOR MANUFACTURING COMPANY LTD., HSINCHU (TW)

(72) Inventors: CHIH-HSUAN TAI, TAIPEI CITY (TW); MING-CHUNG WU, HSINCHU (TW); HSIANG-TAI LU, HSINCHU COUNTY (TW)

(21) Appl. No.: 18/433,460

(22) Filed: Feb. 6, 2024

(51) Int. Cl. H01L 23/498; H01L 21/48

(52) U.S. Cl. CPC H01L 23/49838; H01L 21/486; H01L 23/49827

(57) ABSTRACT

A redistribution layer, a semiconductor device, and a method of manufacturing the semiconductor device are provided. The redistribution layer includes a dielectric stack, a plurality of signal connections, a plurality of power/ground connections, and a plurality of guard members. The dielectric stack is disposed on the substrate. The plurality of signal connections penetrate through the dielectric stack. The plurality of power/ground connections extend through the dielectric stack. The plurality of guard members are disposed in the dielectric stake and arranged respectively around the plurality power/ground connections.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Due to the miniaturized scale of the semiconductor device, more than one IC chip may be integrated into a semiconductor package. In some instances, the chip-to-chip communication between the IC chips being integrated may be provided by way of an interposer or a redistribution layer (RDL) structure. The chip-to-chip communication involves not only conductive features carrying logic signals but also those carrying input/output (I/O) signals. While existing chip-to-chip communication in semiconductor packages is generally adequate for their intended purposes, it is not satisfactory in all aspects.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a schematic bottom view of a semiconductor device in accordance with some embodiments of the present disclosure.

FIG. 2 is a schematic cross-sectional view of a semiconductor device along a line A-A′ illustrated in FIG. 1.

FIG. 3 is a schematic cross-sectional view of a semiconductor device along a line B-B′ illustrated in FIG. 1 in accordance with some embodiments of the present disclosure.

FIG. 4 is a flowchart of a method of manufacturing a semiconductor device, in accordance with some embodiments of the present disclosure.

FIGS. 5A to 5K are cross-sectional views of intermediate stages of a method of manufacturing a semiconductor device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence, order, or importance unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range (e.g., within 10%, 5%, 1%, or 0.5% of a given value or range) that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another end point or between two endpoints. All ranges disclosed herein are inclusive of the endpoints, unless specified otherwise.

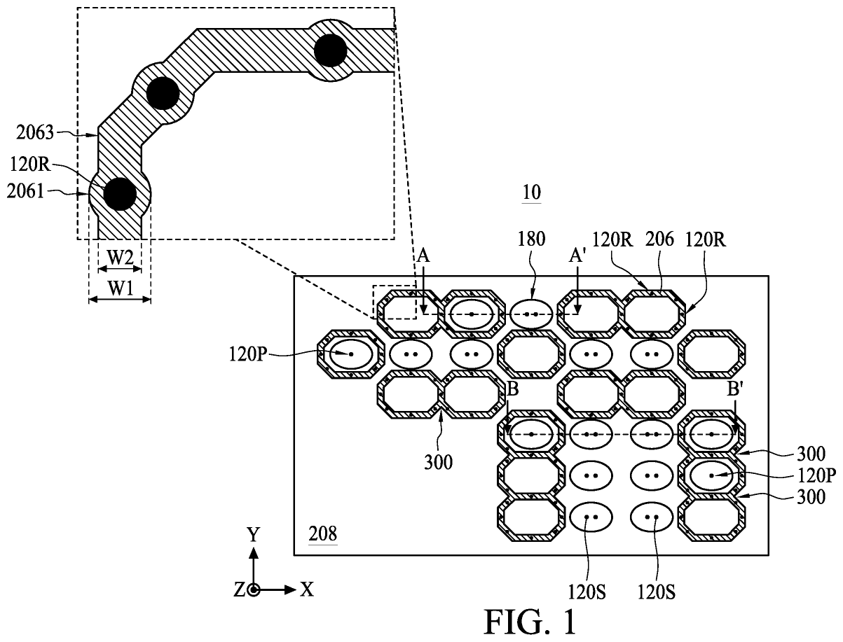

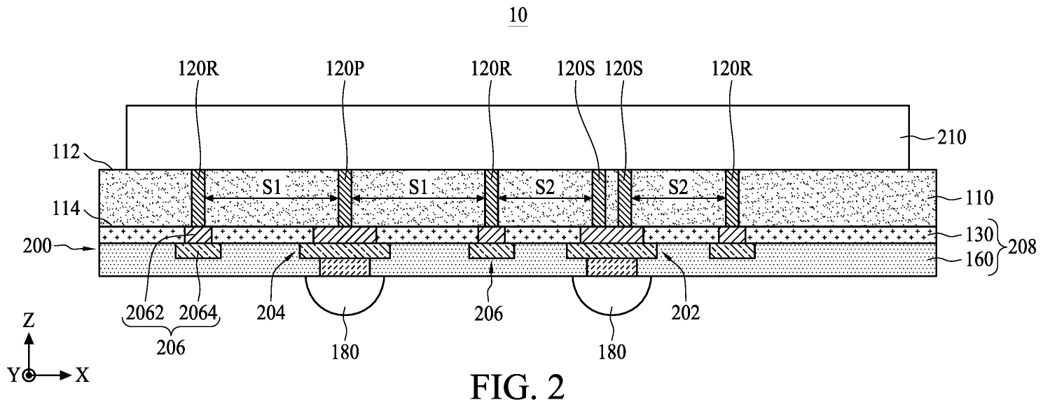

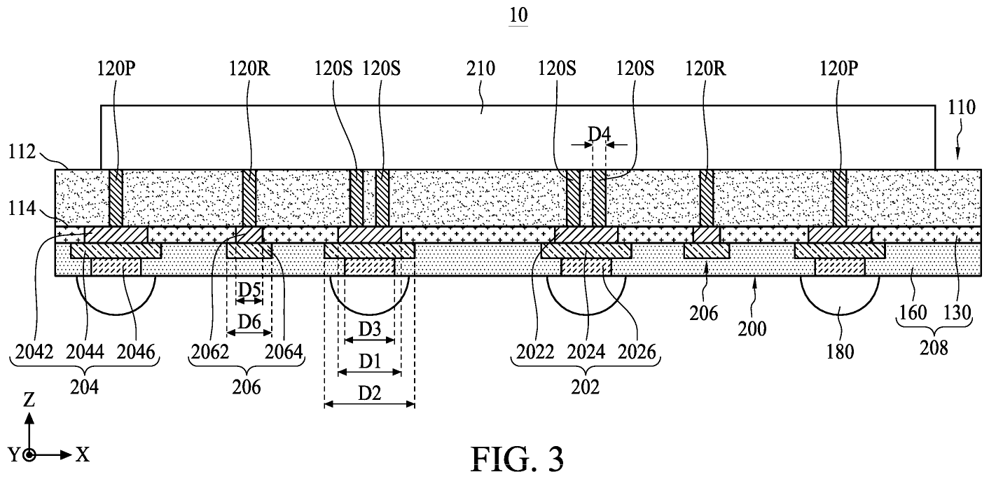

FIG. 1 is a schematic bottom view of a semiconductor device 10 in accordance with some embodiments of the present disclosure, FIG. 2 is a schematic cross-sectional view of a semiconductor device along a line A-A′ illustrated in FIG. 1, and FIG. 3 is a schematic cross-sectional view of a semiconductor device along a line B-B′ illustrated in FIG. 1 in accordance with some embodiments of the present disclosure. Referring to FIGS. 1 to 3, the semiconductor device 10 includes a substrate 110, a plurality of signal conductive vias 120S, a plurality of power/ground conductive vias 120P, a plurality of guard conductive vias 120R, a plurality of bumps 180, a redistribution layer 200, and one or more chips 210 (or dies 210). In some embodiments, the signal conductive vias 120S, the power/ground conductive vias 120P, and the guard conductive vias 120R may be collectively referred to as conductive vias 120. The redistribution layer 200 and the chip 210 are arranged at opposite sides of the substrate 110 and electrically coupled with each other through the conductive vias 120 penetrating through the substrate 110. The redistribution layer 200 includes a plurality of signal connections 202 over the substrate 110, a plurality of power/ground connections 204, and a plurality of guard members 206. The plurality of guard members 206 are arranged respectively around the power/ground connections 204. In some embodiments, the signal conductive vias 120S are electrically and physically connected to the signal connections 202, the power/ground conductive vias 120P are electrically and physically connected to the power/ground connections 204, and the guard conductive vias 120R are electrically and physically connected to the guard members 206. More details of each component are given below.

In some embodiments, the substrate 110 is a semiconductive substrate. In some embodiments, the substrate 110 is an interposer or a wafer. In some embodiments, the substrate 110 is a silicon substrate or silicon wafer. In some embodiments, the substrate 110 includes semiconductive material such as silicon, germanium, gallium, arsenic, and combinations thereof. In some embodiments, the substrate 110 includes material such as ceramic, glass, organic, etc. In some embodiments, the substrate 110 is a glass substrate or glass wafer. In some embodiments, the substrate 110 is in a quadrilateral, rectangular, square, polygonal, or any other suitable shapes.

In some embodiments, the substrate 110 includes a first surface 112 and a second surface 114 opposite to the first surface 112. In some embodiments, the first surface 112 is a front side or an active side that the chip 210 is disposed thereon. In some embodiments, the second surface 114 is a back side or an inactive side. The chip 210 is a semiconductor device designed for an intended purpose such as individually being a logic die, a central processing unit (CPU) die, a memory die, combinations of these, or the like. The chip 210 may include integrated circuit devices (not shown), such as transistors, capacitors, inductors, resistors, first metallization layers (not shown), and the like, therein, as desired for a particular functionality. The chip 210 may be attached to the substrate 110 using, e.g., an adhesive material, although any suitable method of attachment may alternatively be utilized.

The conductive vias 120 may serve to provide a connection between the redistribution layer 200 and the chip 210. In some embodiments, the conductive vias 120 include material such as copper, silver, nickel, aluminum, gold, titanium or tungsten, etc. In some embodiments, the conductive vias 120 are through silicon vias (TSVs). In some embodiments, when the semiconductor device 10 includes two or more chips 210, the chips 210 can be electrically coupled to each other through the conductive vias 120 and the redistribution layer 200.

The redistribution layer 200 is disposed at the back side of the substrate 110. In some embodiments, the redistribution layer 200 re-routes paths from the conductive vias 120 (i.e., the signal conductive vias 120S, the power/ground conductive vias 120P, and the guard conductive vias 120R) to redistribute I/O terminals of the semiconductor device 10. The redistribution layer 200 may be formed of alternating layers of dielectric and conductive material. For example, the redistribution layer 200 may include a dielectric stack 208, the signal connections 202 and the power/ground connections 204 surrounded by the dielectric stack 208. The guard members 206 are enclosed on the dielectric stack 208. The signal connections 202 are used for carrying information bearing signals. The power/ground connections 204 are electrically coupled to an operation power provided on voltage rails. The guard members 206 are electrically grounded.

In some embodiments, each of the signal connections 202 is a three-layered structure that works to carry signals to and from the signal conductive vias 120S. The signal connections 202 extend through the dielectric stack 208. Each of the signal connections 202 may be connected to one or more of the signal conductive vias 120S. For example, each signal connections 202 is connected to two signal conductive vias 120S.

Each of the power/ground connections 204 is also a three-layered structure. The power/ground connections 204 work to distribute power to the chip(s) 210 and supply a ground potential for the chip(s) 210. The power/ground connections 204 penetrate through the dielectric stack 208. In some embodiments, each of the power/ground connections 204 is connected to one of the power/ground conductive vias 120P.

Each of the guard members 206 is a two-layered structure. The guard members 206 may have a ring shape when view from a bottom view and may be connected to multiple guard conductive vias 120R. In some embodiments, the guard member 206 forms a closed ring. The guard members 206 are circular or polygonal. In some embodiment, the guard members 206 are octagonal-shaped with a symmetric geometry to reduce an area occupied by the guard members 206. The guard members 206 may have other geometries and may be symmetrical or asymmetrical. For example, the guard members 206 may be elliptical, triangular, trapezoidal, parallelogram, pentagonal, hexagonal, or other shape such as another polygonal shape, a random shape having a staggered line that is primarily curved alone or in combination with a straight or a staggered line, or other suitable shape. The guard members 206 around neighboring power/ground connections 204 may be connected to each other. In some embodiments, the connected guard members 206 have a shared segment 300, as illustrated in FIG. 1, thereby making it possible to reduce the amount of space occupied by the redistribution layer 200.

In some embodiments, each guard member 206 can have a non-uniform thickness. For example, each guard member 206 may include a plurality of first segment 2061 right beneath the guard conductive vias 120R, and a plurality of second segments 2063 connected to adjacent first segments 2061. The first segments 2061 have a variable width W1, and the second segments 2063 have a substantially uniform width W2. The width W1 is greater than the width W2. In some embodiments, the width W1 of the first segment 2061 may be equal to the width W2 of the second segment 2063, depending on different product design.

Referring to FIGS. 2 and 3, the dielectric stack 208 may include a first dielectric layer 130 and a second dielectric layer 160. The first dielectric layer 130 is placed on the second surface 114 of the substrate 110. The first dielectric layer 130 may be disposed between the second dielectric layer 160 and second surface 114 of the substrate 110. The first dielectric layer 130 and the second dielectric layer 160 may be made of the same or different materials. In some embodiments, the first dielectric layer 130 is made of insulating material including nitride, such as silicon nitride (SiN) or silicon oxynitride (SiON), and the second dielectric layer 160 is formed of polymer such as polyimide or a polyimide derivative.

Each of the signal connections 202 includes an upper conductive line 2022, a middle conductive line 2024, and a lower conductive line 2026. The upper conductive lines 2022 of the signal connections 202 are placed on the substrate 110 and connected to at least one of the signal conductive vias 120S. In some embodiments, the upper conductor lines 2022 of the signal connections 202 are in electrically contact with a first electrical routing, thereby forming an upper signal wire.

The middle conductive lines 2024 of the signal connections 202 are stacked on the upper conductive lines 2022 thereof. In some embodiments, the middle conductive lines 2024 are in electrically contact with a second electrical routing to form a middle signal wire. The lower conductive lines 2026 of the signal connections 202 are stacked on the middle conductive lines 2024 thereof. In some embodiments, the lower conductive lines 2026 of the signal connections 202 are in electrically contact with a third electrical routing to form a lower signal wire.

The upper conductive lines 2022 of the signal connections 202 may be designed in various shapes from a bottom-view perspective, including but limited to circular, triangular, square, rectangle, or any polygon shape which could provide for necessary contact with the signal conductive vias 120S. The above list only provides a few exemplary embodiments. Other suitable shapes may also be considered as proper upper conductive lines 2022 of the signal connections 202 for the same purpose. Each upper conductive line 2022 of the signal connections 202 substantially has the same size to each other, and even as a size difference exists between any two of the upper conductive lines 2022, the size difference between any two of the upper conductive lines 2022 is in an acceptable tolerance, and thus is negligible.

The middle conductive lines 2024 and the lower conductive lines 2026 of the signal connections 202 may have a substantially the same shape as the upper conductive lines 2022 thereof. In some embodiments, the upper conductive line 2022, the middle conductive line 2024, and the lower conductive line 2026 of each signal connection 202 have different sizes. For example, the upper conductive line 2022, the middle conductive line 2024, and the lower conductive line 2026 of each signal connection 202 are circular-shaped. As shown in FIG. 3, the upper conductive line 2026 has a first diameter D1, the middle conductive line 2024 has a second diameter D2 greater than the first diameter D1, and the lower conductive line 2026 has a third diameter D3 less than the first diameter D1. In some embodiments, the signal conductive vias 120S have a fourth diameter D4, and the first diameter D1 is greater than two times the fourth diameter D4. However, any other suitable dimensions may alternatively be utilized.

Each of the power/ground connections 204 includes an upper conductive line 2042, a middle conductive line 2044, and a lower conductive line 2046 sequentially stacked on the substrate 110. The upper conductive lines 2042 of the power/ground connections 204 extend through the first dielectric layer 130. In some embodiments, some of the upper conductive lines 2042 of the power/ground connections 204 are in electrically contact with a fourth electrical routing (not shown) to form a first upper power/ground wire, and the other upper conductive lines 2042 of the power/ground connections 204 are in electrically contact with a fifth electrical routing (not shown) to form a second upper power/ground wire. The first upper power/ground wire and the second upper power/ground wire may be used for distribution powers having different potentials. The first upper power/ground wire is electrically isolated form the second upper power/ground wire for preventing short circuit.

The upper conductive lines 2042 of the power/ground connections 204 may have substantially the same shape and dimension as the upper conductive lines 2022 of the signal connections 202. Alternatively, the upper conductive lines 2022 and 2042 have different shapes. Although the upper signal wire, the first upper power/ground wire and the second upper power/ground wire are at a same horizontal level in the Z-direction, the upper signal wire is electrically isolated from the first upper power/ground wire and the second upper power/ground wire.

The middle conductive lines 2044 and the lower conductive lines 2046 are surrounded by the second dielectric layer 160. In some embodiments, some of the middle conductive lines 2044 of the power/ground connections 204 are in electrically contact with a sixth electrical routing (not shown) to form a first middle power/ground wire, and the other middle conductive lines 2044 of the power/ground connections 204 are in electrically contact with a seventh electrical routing (not shown) to form a second middle power/ground wire. In some embodiments, the first middle power/ground wire is aligned with the first upper power/ground wire in the Z-direction, and the second middle power/ground wire is aligned with the second upper power/ground wire in the Z-direction. The middle signal wire, the first middle power/ground wire, and the second middle power/ground wire are at substantially the same horizontal level in the Z-direction and electrically isolation from each other. The middle conductive lines 2044 of the power/ground connections 204 may have substantially the same shape and dimension as the middle conductive lines 2024 of the signal connections 202.

Similarly, some of the lower conductive lines 2046 of the power/ground connections 204 are in electrically contact with an eighth electrical routing (not shown) to form a first lower power/ground wire, and the other lower conductive lines 2046 of the power/ground connections 204 are in electrically contact with a ninth electrical routing (not shown) to form a second lower power/ground wire. In some embodiments, the first lower power/ground wire is aligned with the first middle power/ground wire in the Z-direction, and the second lower wire is aligned with the second middle power/ground wire in the Z-direction. The lower signal wire, the first lower power/ground wire, and the second lower power/ground wire are at substantially the same horizontal level in the Z-direction and electrically isolation from each other. The lower conductive lines 2046 of the power/ground connections 204 may have substantially the same shape and dimension as the lower conductive lines 2026 of the signal connections 202.

Each of the guard member 206 includes an upper conductive line 2062 and a lower conductive line 2064 sequentially stacked on the substrate 110. The upper conductive lines 2062 of the guard member 206 are surrounded by the first dielectric layer 130, and the lower conductive lines of the guard members 206 are encapsulated by the second dielectric layer 160.

The upper conductive lines 2062 of the guard members 206 may be in electrically contact with a tenth electrical routing (not shown) to form an upper guard wire. The upper conductive lines 2062 of the guard members 206 may have substantially the same shape as the upper conductive lines 2022 of the signal connections 202. In some embodiments, the upper conductive lines 2062 of the guard members 206 and the upper conductive lines 2022 of the signal connections 202 have a different diameters. For example, the upper conductive lines 2062 of the guard members 206 may have a fifth diameter D5 less than the first diameter D1 of the upper conductive lines 2022 of the signal connections 202. The fifth diameter D5 is greater than the fourth diameter D4. Alternatively, the upper conductive lines 2062 of the guard members 206 and the upper conductive lines 2022 of the signal connections 202 may have the same diameter.

The upper guard wire is arranged at the same horizontal level with the upper signal wire in the Z-direction, the first upper power/ground wire, and the second upper power/ground wire. In some embodiments, the upper guard wire is electrically isolated from the upper signal wire and at least one of the first and second upper power/ground wire. The upper guard wire may be electrically coupled to one of the first and second upper power/ground wire that applies the ground potential. The upper guard wire is thereby fixed at the ground potential.

The lower conductive lines 2064 of the guard members 206 may be in electrically contact with an eleventh electrical routing (not shown) to thereby form a lower guard wire. In some embodiments, the lower conductive lines 2064 overlays the upper conductive lines 2062. The lower conductive lines 2064 of the guard members 206 may have substantially the same shape as the lower conductive lines 2026 of the signal connections 202. However, the lower conductive lines 2064 of the guard members 206 may have a sixth diameter D6 different from the second diameter D2 of the upper conductive lines 2022 of the signal connections 202. For example, the sixth diameter D6 is less than the second diameter D2.

The lower guard wire is at the same horizontal level with the middle signal wire in the Z-direction, the first middle power/ground wire, and the second middle power/ground wire. In some embodiments, the lower guard wire is electrically isolated from the middle signal wire and at least one of the first and second middle power/ground wire. The lower guard wire may be electrically coupled to one of the first and second middle power/ground wire that applies the ground potential.

In some embodiment, the upper conductive lines 2022, 2042 and 2062 include a same material, the middle conductive lines 2024, 2044 and the lower conductive line 2064 include a same material, and the lower conductive lines 2426 and 2046 include a same material, but the disclosure is not limited thereto.

The bumps 180 are formed on and electrically connected to the all of the lower conductive lines 2026 of the signal connections 202. The bumps 180 are further formed on and electrically to some of the lower conductive lines 2046 of the power/ground connections 204. The bump 180 can include solder bumps, such as eutectic solder bumps. Alternatively, the solder bumps 180 can be formed of copper bumps or other metal bumps formed of gold, silver, nickel, tungsten, aluminum, other metals, and/or alloys thereof. The solder bump 180 can also include controlled collapse chip connection (C4) bumps.

Because the pattern for the bumps 180 has to correspond to the pattern of the signal connections 202 and the power/ground connections 204. Design rules for the pattern of the bumps 180 include minimum pitch requirements from the design rules for the signal connections 202 and the power/ground connections 204 of the redistribution layer 200. Minimum spacing between the signal connections 202 and the power/ground connections 204 is needed to prevent solder bridges and shorts between the bumps 180.

The desired rule limits the minimum spacing between the conductive vias 120 in the substrate 110 to ensure robust device manufacturing. In the semiconductor device made without the guard members 206, the spacing between conductive vias 120 is generally greater than 110 μm. Some separation is used to keep noise coupling within acceptable limits regardless of what shielding is used. On the other hand, it is desirable to limit the amount of separation in order to avoid wasting device area. The semiconductor device of the present disclosure includes the guard members 206 that serve to shield the signal connections 202 from unintended electrical coupling. The guard members 206 are encapsulated by the dielectric stack 208, without the need for additional bumps 180 that would add cost and complexity. As a result, a spacing distance S1 between the conductive via 120S connected to the signal connection 202 and the conductive vias 120R connected to adjacent guard member 206 can be reduced. A spacing distance S2 between the conductive via 120P connected to the power/ground connection 204 and the conductive vias 120R connected to adjacent guard member 206 can be reduced. In some embodiments, the spacing distance S1 and S2 is less than 100 μm. For example, the spacing distance S1 and S2 may be between approximately 60 μm and approximately 80 μm.

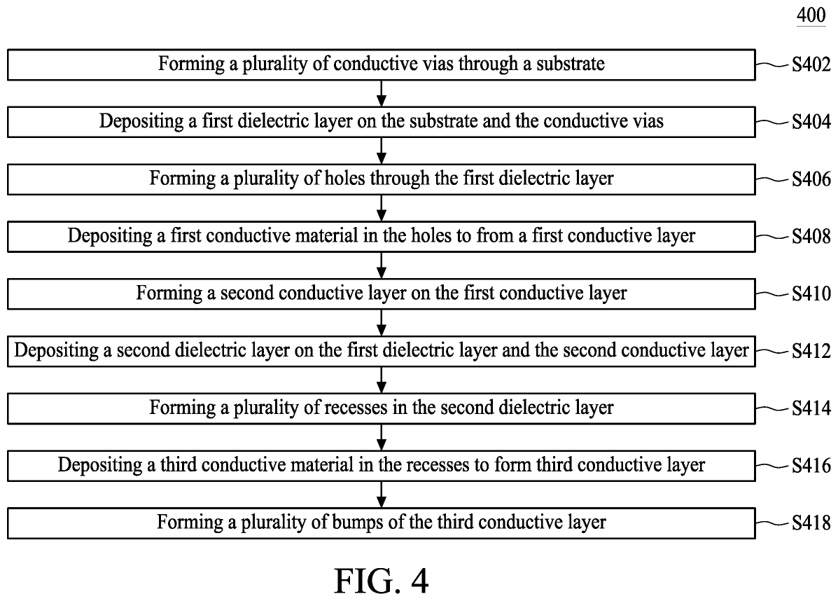

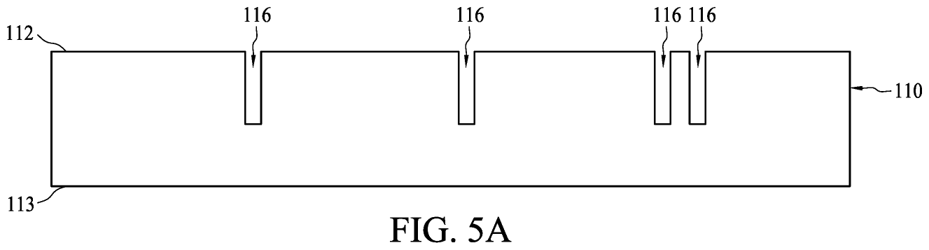

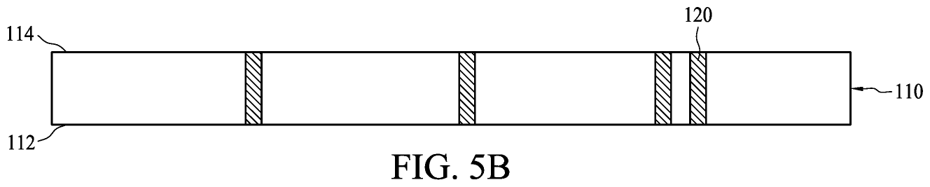

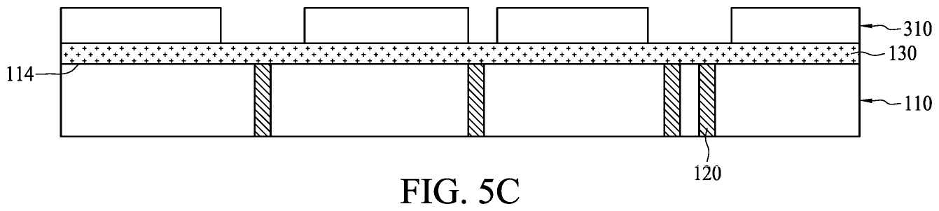

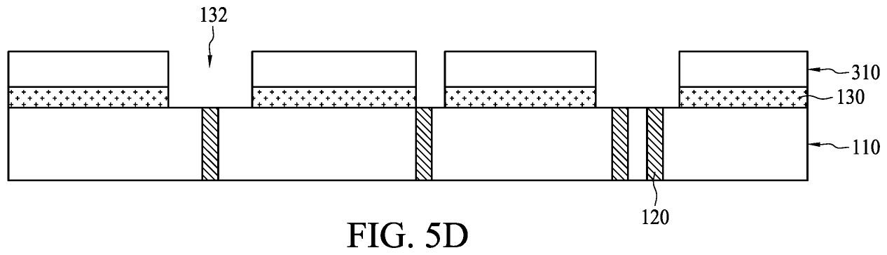

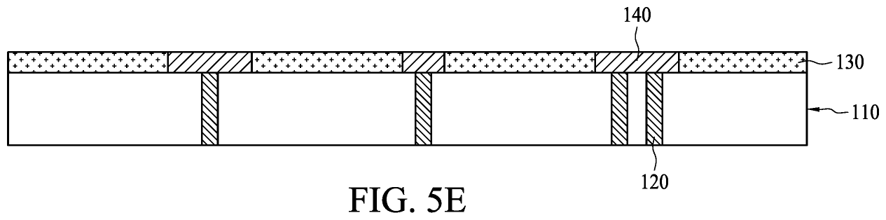

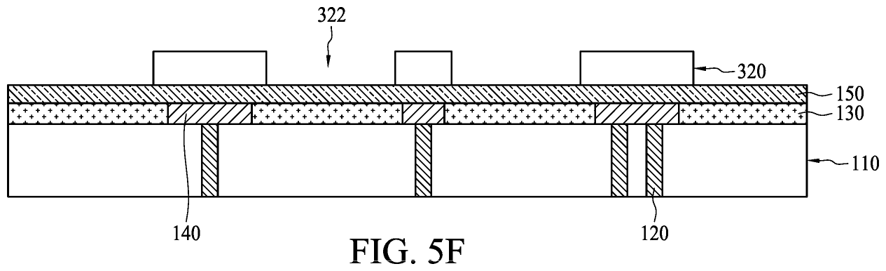

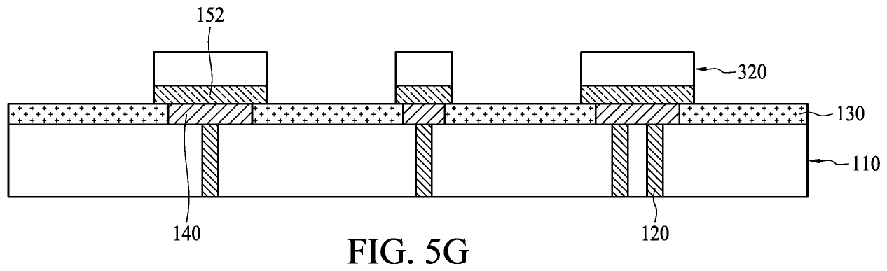

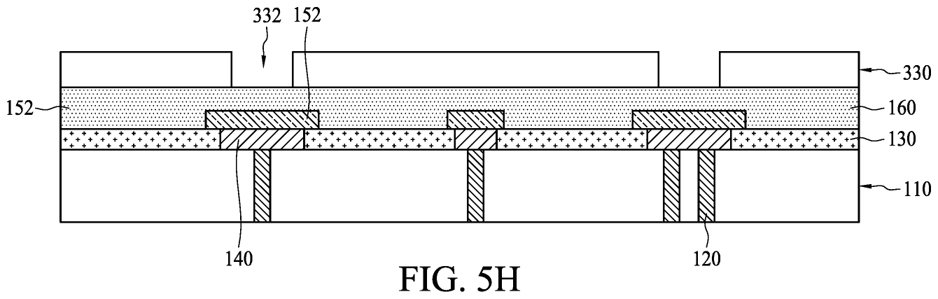

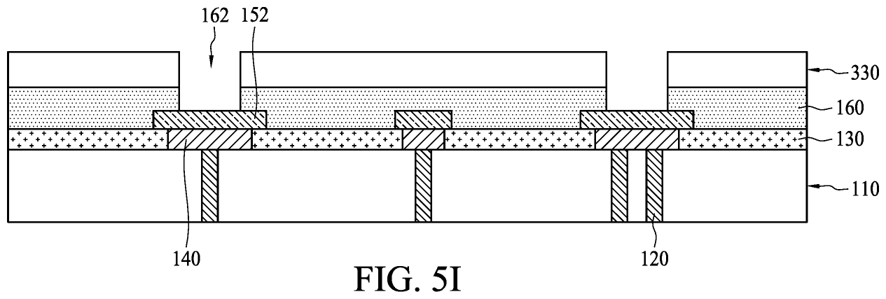

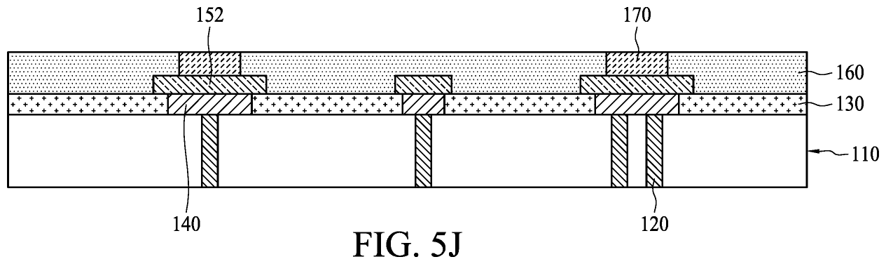

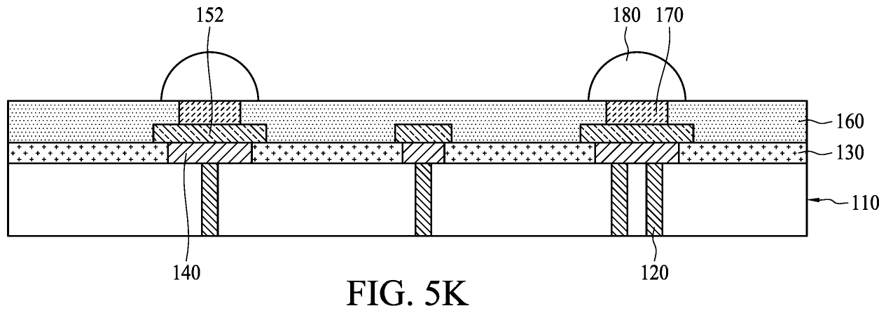

FIG. 4 is a flowchart of a method 400 of manufacturing a semiconductor device 10, in accordance with some embodiments of the present disclosure. FIGS. 5A to 5J are cross-sectional views of intermediate stages of the method 400 of manufacturing the semiconductor device 10, in accordance with some embodiments of the present disclosure. In the following discussion, the manufacture stages shown in FIGS. 5A to 5J are discussed in reference to the operations shown in FIG. 4. It should be understood that additional steps can be provided before, during, and after the steps shown in FIG. 4, and some of the steps described below can be replaced or eliminated, for additional embodiments of the method 400. The order of the steps may be changed.

Referring to FIGS. 5A and 5B, a substrate 110 is received, and a plurality of conductive vias 120 are formed through the substrate 110 according to step S402 in FIG. 4. In some embodiments, the substrate 110 may be a silicon substrate. Alternatively, the substrate 110 may comprise another elementary semiconductor, such as germanium; a compound semiconductor including silicon carbide; an alloy semiconductor including silicon germanium; or a combination thereof.

The formation of the conductive vias 120 may include following operations. In some embodiments, a plurality of trenches 116 are formed into a front side of the substrate 110. As shown in FIG. 5A, the trenches 116 extend from a first surface 112 into the substrate 110 to a predetermined depth. A conductive material is formed to fill the trenches 116. The substrate 110 is thinned from a bottom surface 113 opposite to the first surface 112 until the conductive material of is exposed. The trenches 116 may be formed by applying and developing a suitable photoresist (not shown), and then etching portions of the substrate 110. The conductive material may comprise copper, although other suitable materials such as aluminum, alloys, doped polysilicon, or the like, may alternatively be utilized. The conductive material may be formed by electroplating copper onto the substrate 100, filling and overfilling the trenches 116. Once the trenches 116 have been filled, excess conductive material (i.e., outside of the trenches) may be removed through a planarization operation such as chemical mechanical polishing (CMP), although any suitable removal operation may be used. The substrate 110 is thinned using a grinding operation. After the grinding operation, backside silicon is removed to expose the conductive vias 120.

In some embodiments, an insulative liner and a glue layer (not shown) can be optionally formed between the conductive material and the substrate 110. In some embodiments, the insulative liner and the glue layer are conformal layers and sequentially deposited in the trenches 116 prior to the deposition of the conducive material. The insulative liner may be used to prevent the conductive material from shorting to the substrate 100. The glue layer helps to adhere the insulative liner and the conductive material. The insulative liner may be either tetraethylorthosilicate (TEOS) or silicon nitride, although any suitable dielectric may alternatively be used. The glue layer may be made of titanium, titanium nitride, tantalum, tantalum nitride, or the like. Examples of operations for depositing the insulating line and the glue layer include chemical vapor deposition (CVD), physical vapor deposition (PVD), atomic layer deposition (ALD), and other applicable operations. The grinding operation for thinning the substrate 110 may be performed until the insulative liner and the glue layer are completely removed from the bottoms of the conductive vias 120.

Referring to FIG. 5C, after backside grinding, a first dielectric layer 130 is formed over a second surface 114 of the substrate 110 and the conductive vias 120 according to step S404 in FIG. 4. The first dielectric layer 130 may formed of material such as polyimide (PI), polybenzoxazole (PBO), BCB, epoxy, silicone, acrylates, nano-filled pheno resin, siloxane, a fluorinated polymer, polynorbornene, an oxide, a nitride, or the like. The first dielectric layer 130 may be deposited with a substantially uniform thickness using an acceptable deposition operation such as a spin-on coating operation, a CVD operation, a PVD operation, an ALD operation, or the like.

After the first dielectric layer 130 is completely formed, a first patterned mask layer 310 is formed over the first dielectric layer 130. The first patterned mask layer 310 may be a photoresist layer and/or a hardmask layer.

Referring to FIG. 5D, a first etching operation is performed with the first pattered mask layer 310 in place to form a series of holes 132 through the first dielectric layer 130 according to step S406 in FIG. 4. As shown in FIG. 5D, the first dielectric layer 130 is etched until the conductive vias 120 and portions of the substrate 110 around the conductive vias 120 are exposed. In some embodiments, the first dielectric layer 130 is anisotropically etched by a plasma-based etching operation, such as a reactive ion etching (RIE) operation, or the like. After the holes 132 are formed, the first patterned mask layer 310 is removed in an ashing and/or wet strip operation, for example.

Referring to FIG. 5E, a first conductive material is provided to fill the holes 132 according to step S408 in FIG. 4. Accordingly, a first conductive layer 140 is formed. The first conductive layer 140 penetrate through the first dielectric layer 130 and are electrically connect to the conductive vias 120. The first conductive layer 140 may include the abovementioned upper conductive lines 2022, 2042 and 2062. Examples of the first conductive material include, but are not limited to, tungsten (W), copper (Cu), aluminum (Al), cobalt (Co), nickel (Ni), an aluminum-copper alloy (AlCu), an aluminum-copper-silicon alloy, and the like. The first conductive material may be formed or deposited by an electro-chemical plating process, a CVD operation, a PVD operation, an ALD operation, or other applicable deposition operation. After the first conductive material fills or is deposited in the holes 132, excess portions of the first conductive material are removed to expose a top surface of the first dielectric layer 130. The excess portions of the conductive material may be removed by a CMP operation.

Referring to FIG. 5F, a second conductive material 150 is deposited on the first dielectric layer 130 and the first conductive layer 140. The second conductive material 150 may include copper, titanium, nickel, aluminum, compositions thereof, or the like, and may be formed using any appropriate operation, such as by metal foil lamination, CVD, PVD, and so forth. Subsequently, a second patterned mask layer 320 is formed on the second conductive material 150. The second patterned mask layer 320 includes one or more second openings 322, wherein portions of the second conductive material 150 are exposed through the second openings 322. In some embodiments, the second patterned mask layer 320 may overlap the first conductive layers 140, as shown in FIG. 5F.

Referring to FIG. 5G, a second etching operation is performed to pattern the second conductive material 150 according to step S410 in FIG. 4. Therefore, a second conductive layer 152 is formed. The second conductive layer 152 may include the above mentioned middle conductive lines 2024, 2044 and 2064. In some embodiments, the second conductive layer 152 is aligned with the first conductive layer 140 in the Z-direction.

Referring to FIG. 5H, a second dielectric layer 160 is deposited on the first dielectric layer 130 and the second conductive layer 152 according to step S412 in FIG. 4. In some embodiments, the second dielectric layer 160 may be planarized, such as by a CMP operation, to have a substantially planar top surface. The second dielectric layer 160 may be formed of polymer, such as an epoxy, polyimide, benzocyclobutene (BCB), polybenzoxazole (PBO), and the like, although other relatively soft, often organic, dielectric materials can also be used. The second dielectric layer 160 including polymer is soft, and hence has the function of reducing inherent stresses on the substrate 110. In addition, the second dielectric layer 160 is easily formed to thickness of tens of microns.

After the second dielectric layer 160 is formed, a third patterned mask layer 330 is formed on the second dielectric layer 160. The third patterned mask layer 330 is utilized to pattern the second dielectric layer 160, and includes one or more third openings 332 exposing one or more portions of the second dielectric layer 160.

Referring to FIGS. 51, a third etching operation is performed to form one or more recesses 162 in the second dielectric layer 160 according to step S414 in FIG. 4. Portions of the second conductive layer 152 are exposed through the recesses 162 for allowing subsequent material formation.

Referring to FIG. 5J, a third conductive material is deposited in the recesses 162 according to step S418 in FIG. 4, thereby forming a third conductive layer 170. In some embodiments, the third conductive layer 170 is an under-bump-metallurgy (UBM) layer. The third conductive material is deposited on the exposed second conductive layer 152. The third conductive layer 170 may include the abovementioned lower conductive lines 2026 and 2046. In one embodiment, an electroless Cu deposition is performed to selectively plate a Cu layer on the exposed portion of the second conductive layer 152.

Referring to FIG. 5K, a plurality of bumps 180 can then be joined to the third conductive layer 170 according to step S420 in FIG. 4. The bumps 180 are placed on the lower signal wire and the first and second lower power/ground wires. The bumps 180 are formed using a variety of known solder deposition methods including, but not limited to, ball drop, paste screening, solder bumps (C4), as well as future generations of C4 solder operations, such as C4-NP operation. By using each solder deposition method, a variety of solders may be used for improved performance. Lead-free solder materials are preferred and are chosen based upon improving mechanical and thermal cycling performances, as well as to improve electromigration behavior. Any type of current and/or future generation of lead-free solder or lead-free solder alloys including, but not limited to, Sn, Sn/Ag, Sn/Ag/Cu, Sn/Cu, or the like. For example, solders such as SnCu (0.7%) or SnAg (1-3%), SnAgCu (305 or 309) can be used which are difficult to plate.

In accordance with some embodiments of the present disclosure, a semiconductor structure includes a substrate; a redistribution layer, and a plurality of solder bumps. The redistribution layer includes a dielectric stack disposed on the substrate; a plurality of signal connections penetrating through the dielectric stack; a plurality of power/ground connections extending through the dielectric stack; and a plurality of guard members disposed in the dielectric stack. The plurality of solder bumps are disposed on the dielectric stack and connected to the plurality of signal connections and at least one of the plurality of power/ground connections. Each power/ground connection is surrounded by one of the guard members.

In accordance with some embodiments of the present disclosure, a semiconductor device includes: a substrate; a chip disposed at a first side of the substrate; a plurality of signal conductive vias extending through the substrate; a plurality of power/ground conductive vias extending through the substrate; a plurality of guard conductive vias extending through the substrate; a redistribution layer disposed at a second side of the substrate, wherein the second side is opposite to the first side, and the redistribution layer includes: a dielectric stack placed on the substrate; a plurality of signal connections penetrating through the dielectric stack, wherein the signal connections are connected to the plurality of signal conductive vias; a plurality of power/ground connections extending through the dielectric stack, wherein the plurality of power/ground connections are connected to the power/ground conductive vias; and a plurality of guard member disposed in the dielectric stack and connected to the plurality of guard conductive vias. The plurality of power/ground connections are surrounded by the plurality of guard members, respectively.

In accordance with some embodiments of the present disclosure, a method of a semiconductor device includes steps of: depositing a first dielectric layer on a substrate; forming a first conductive layer extending through the first dielectric layer, wherein the first conductive layer comprises an upper layer of a signal connection, a upper layer of a power/ground connection, and an upper layer of a guard member, wherein the upper layer of the signal connection, the upper layer of the power/ground connection, and the upper layer of the guard member are electrically isolated from each other; forming a second conductive layer on the first conductive layer, wherein the second conductive layer comprises a middle layer of the signal connection connected to the upper layer of the signal connection, a middle layer of the power/ground connection connected to the upper layer of the power/ground connection, and a lower layer of the guard member connected to the upper layer of the guard member; depositing a second dielectric layer to cover the first dielectric layer and the second conductive layer; and forming a third conductive layer in the second dielectric layer, wherein the third conductive layer comprises a lower layer of signal connection connected to the middle layer of the signal connection and a lower layer of power/ground connection connected to the middle layer of power/ground connection.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a redistribution layer, comprising:
a dielectric stack disposed on the substrate;
a plurality of signal connections penetrating through the dielectric stack;
a plurality of power/ground connections extending through the dielectric stack; and
a plurality of guard members disposed in the dielectric stack; and
a plurality of solder bumps disposed on the dielectric stack and connected to the plurality of signal connections and at least one of the plurality of power/ground connections,
wherein each power/ground connection is surrounded by one of the guard members.

2. The semiconductor structure of claim 1, wherein the plurality of guard members are encapsulated by the dielectric stack and are in contact with the substrate.

3. The semiconductor structure of claim 1, wherein the plurality of guard members in the dielectric stack have a non-uniform diameter.

4. The semiconductor structure of claim 1, wherein:
the dielectric stack comprises a first dielectric layer disposed on the substrate and a second dielectric layer disposed on the first dielectric layer; and
the plurality of guard members comprise an upper conductive line surrounded by the first dielectric layer and a lower conductive line connected to the upper conductive line and encapsulated by the second dielectric layer.

5. The semiconductor structure of claim 4, wherein the plurality of power/ground connections comprise an upper conductive line, a middle conductive line, and a lower conductive line sequentially stacked on the substrate, the upper conductive lines of the power/ground connections are surrounded by the first dielectric layer and electrically isolation from the upper conductive lines of the guard members, the middle conductive lines and the lower conductive lines of the power/ground connections are surround by the second dielectric layer and electrically isolated from the lower conductive lines of the guard members, and
the lower conductive lines of the guard members and the middle conductive lines of the power/ground connections are at a same horizontal level.

6. The semiconductor structure of claim 4, wherein:
the plurality of signal connections comprise an upper conductive line, a middle conductive line, and a lower conductive line sequentially stacked on the substrate, the upper conductive lines of the signal connections are surrounded by the first dielectric layer and electrically isolation from the upper conductive lines of the guard members and from the upper conductive lines of the power/ground connections, the middle conductive lines and the lower conductive lines of the signal connections are surround by the second dielectric layer and electrically isolation from the lower conductive lines of the guard members, the middle conductive lines of the power/ground connections, and the lower conductive line of the power/ground connections, and
the lower conductive lines of the guard members and the middle conductive lines of the signal connections are at a same horizontal level.

7. The semiconductor structure of claim 1, wherein the plurality of guard members around the neighboring power/ground connections are connected to each other, and the connected guard members have a shared segment.

8. A semiconductor device, comprising:
a substrate;
a chip disposed at a first side of the substrate;
a plurality of signal conductive vias extending through the substrate;
a plurality of power/ground conductive vias extending through the substrate;
a plurality of guard conductive vias extending through the substrate;
a redistribution layer disposed at a second side of the substrate, wherein the second side is opposite to the first side, and the redistribution layer comprises:
a dielectric stack placed on the substrate;
a plurality of signal connections penetrating through the dielectric stack, wherein the signal connections are connected to the plurality of signal conductive vias;
a plurality of power/ground connections extending through the dielectric stack, wherein the plurality of power/ground connections are connected to the power/ground conductive vias; and
a plurality of guard members disposed in the dielectric stack and connected to the plurality of guard conductive vias,
wherein the plurality of power/ground connections are surrounded by the plurality of guard members, respectively.

9. The semiconductor device of claim 8, further comprising a plurality of solder bumps attached to the plurality of signal connections and at least one of the plurality of power/ground connections.

10. The semiconductor device of claim 8, wherein one of the guard members is coupled to at least two of the guard conductive vias.

11. The semiconductor device of claim 8, wherein:
the dielectric stack comprises a first dielectric layer disposed on the substrate and a second dielectric layer disposed on the first dielectric layer.

12. The semiconductor device of claim 11, wherein the plurality of guard members comprise an upper conductive line surrounded by the first dielectric layer and a lower conductive line connected to the upper conductive line and encapsulated by the second dielectric layer, and
the upper conductive line has a first diameter and the lower conductive line has a second diameter greater than the first diameter.

13. The semiconductor device of claim 12, wherein:
the plurality of signal connections comprise an upper conductive line, a middle conductive lines, and a lower conductive line sequentially stacked on the substrate, the upper conductive lines of the guard members and the upper conductive lines of the signal connections are at a first horizontal level, and
the lower conductive lines of guard members and the middle conductive lines of the signal connections are at a second horizontal level.

14. The semiconductor device of claim 8, wherein the plurality of guard members have a polygonal shape.

15. The semiconductor device of claim 8, wherein each of the guard members comprises a plurality of first segments in contact with the guard conductive vias, respectively, and a plurality of second segment connected to adjacent first segments, the first segments have a first width, and the second segments have a second width less than the first width.

16. The semiconductor device of claim 8, wherein a bottom of each guard member is covered by the dielectric stack.

17. A method of a semiconductor device, comprising:
depositing a first dielectric layer on a substrate;
forming a first conductive layer extending through the first dielectric layer, wherein the first conductive layer comprises an upper layer of a signal connection, a upper layer of a power/ground connection, and an upper layer of a guard member, wherein the upper layer of the signal connection, the upper layer of the power/ground connection, and the upper layer of the guard member are electrically isolated from each other;
forming a second conductive layer on the first conductive layer, wherein the second conductive layer comprises a middle layer of the signal connection connected to the upper layer of the signal connection, a middle layer of the power/ground connection connected to the upper layer of the power/ground connection, and a lower layer of the guard member connected to the upper layer of the guard member;
depositing a second dielectric layer to cover the first dielectric layer and the second conductive layer; and
forming a third conductive layer in the second dielectric layer, wherein the third conductive layer comprises a lower layer of the signal connection connected to the middle layer of the signal connection and a lower layer of the power/ground connection connected to the middle layer of the power/ground connection.

18. The method of claim 17, further comprising forming a plurality of conductive vias extending through the substrate prior to the deposition of the first dielectric layer, wherein the upper layer of the signal connection, the upper layer of the power/ground connection, and the upper layer of the guard member are in contact with the plurality of conductive vias.

19. The method of claim 17, further comprising forming a plurality of bumps attached to the third conductive layer.

20. The method of claim 17, wherein the formation of the second conductive layer comprises:
depositing a layer of conductive material on the first dielectric layer and the first conductive layer; and
performing an etching operation on the layer of the conductive material through a pattered mask layer to thereby form the middle layer of the signal connection, the middle layer of the power/ground connection, and the lower layer of the guard member.
